(19) United States
(12) Patent Application Publication
(10) Pub. No.: US 2025/0246588 A1
(43) Pub. Date: Jul. 31, 2025

(54) CHIP ON WAFER-TO-WAFER-BONDED INTERCONNECT PLATFORM WITH STACKED TSVs

(71) Applicant: Lightmatter, Inc., Boston, MA (US)

(72) Inventors: Kuang Liu, Queen Creek, AZ (US); Krishna Bharath, Portland, OR (US); Ritesh Jain, Portland, OR (US)

(73) Assignee: Lightmatter, Inc., Boston, MA (US)

(21) Appl. No.: 19/036,214

(22) Filed: Jan. 24, 2025

Related U.S. Application Data
(60) Provisional application No. 63/625,261, filed on Jan. 25, 2024.

(51) Int. Cl. H01L 25/16; H01L 23/00; H01L 23/48; H10F 39/90

(52) U.S. Cl. CPC H01L 25/167; H01L 24/08; H01L 24/16; H01L 24/80; H10F 39/90; H01L 23/481; H01L 2224/08146; H01L 2224/16146; H01L 2224/80895; H01L 2224/80896

(57) ABSTRACT

Described herein are electronic-photonic packages including photonic integrated circuits (PIC) that are assembled using hybrid bonding techniques and that communicate with external electronic dies using through silicon vias (TSVs). PICs of the types described herein may be used to support optical-domain communication between electronic devices, whether in the form of inter-chip communication or intra-chip communication. A package may include a PIC comprising a photonic layer comprising a plurality of controllable photonic devices and a first plurality of TSVs, and an electronic layer hybrid-bonded to the photonic layer, the electronic layer comprising a second plurality of TSVs coupled to the first plurality of TSVs, and electronic circuitry configured to control the controllable photonic devices. The package may further include a first electronic die mounted on the PIC and coupled to the first plurality of TSVs or the second plurality of TSVs.

### CROSS-REFERENCE TO RELATED APPLICATION

This application claims the benefit under 35 U.S.C. § 119 (e) of U.S. Provisional Patent Application Ser. No. 63/625,261, entitled “CHIP ON WAFER-TO-WAFER-BONDED INTERCONNECT PLATFORM WITH STACKED TSVs,” filed on Jan. 25, 2024, under Attorney Docket No. L0858.70087US00, which is hereby incorporated herein by reference in its entirety.

### BACKGROUND

Optical transceivers are devices that transmit and receive data using light signals, typically over optical fiber cables. Optical transceivers play a crucial role in telecommunications and data communication networks, converting electrical signals into optical signals for transmission and then converting them back into electrical signals at the receiving end. Wavelength division multiplexing (WDM) is a technology used in optical communication to transmit multiple signals simultaneously over a single optical fiber. WDM achieves this by using different wavelengths (colors) of light for each signal, allowing for efficient use of the fiber's bandwidth and significantly increasing the data-carrying capacity.

### SUMMARY

In some aspects, the techniques described herein relate to an electronic-photonic package, including: a photonic integrated circuit (PIC) including: a photonic layer including a plurality of controllable photonic devices and a first plurality of TSVs; and an electronic layer hybrid-bonded to the photonic layer, the electronic layer including a second plurality of TSVs coupled to the first plurality of TSVs, and electronic circuitry configured to control the controllable photonic devices; and a first electronic die mounted on the PIC and coupled to the first plurality of TSVs or the second plurality of TSVs.

In some aspects, the techniques described herein relate to an electronic-photonic package, further including a second electronic die mounted on the PIC, wherein the controllable photonic devices permit optical communication between the first and second electronic dies.

In some aspects, the techniques described herein relate to an electronic-photonic package, wherein the electronic layer is disposed between the photonic layer and the first electronic die, and the first electronic die is coupled to the second plurality of TSVs.

In some aspects, the techniques described herein relate to an electronic-photonic package, wherein the photonic layer is disposed between the electronic layer and the first electronic die, and the first electronic die is coupled to the first plurality of TSVs.

In some aspects, the techniques described herein relate to an electronic-photonic package, wherein the photonic layer is patterned to include a 1-dimensional or a 2-dimensional array of photonic tiles that are optically coupled to one another and that are copies of a master photonic tile.

In some aspects, the techniques described herein relate to an electronic-photonic package, wherein the master photonic tile has an area that is between 4 cm2 and 10 cm2.

In some aspects, the techniques described herein relate to an electronic-photonic package, wherein the photonic layer has an area that is between 50 cm2 and 700 cm2.

In some aspects, the techniques described herein relate to an electronic-photonic package, wherein the controllable photonic devices include optical modulators and photodetectors, and wherein the electronic circuitry includes modulator drivers coupled to the optical modulators and transimpedance amplifiers coupled to the photodetectors.

In some aspects, the techniques described herein relate to an electronic-photonic package, wherein the electronic die includes a first plurality of serializer-deserializers (SerDes) coupled to the modulator drivers and a second plurality of SerDes coupled to the transimpedance amplifiers.

In some aspects, the techniques described herein relate to an electronic-photonic package, including: a photonic integrated circuit (PIC) including: a photonic layer including a plurality of controllable photonic devices and a first plurality of TSVs; and an electronic layer hybrid-bonded to the photonic layer, the electronic layer including a second plurality of TSVs coupled to the first plurality of TSVs, and electronic circuitry configured to control the controllable photonic devices; and a first plurality of conductive pads formed on a surface of the PIC and coupled to the first plurality of TSVs or the second plurality of TSVs.

In some aspects, the techniques described herein relate to an electronic-photonic package, further including a second plurality of conductive pads formed on the surface of the PIC, wherein the controllable photonic devices permit optical communication between a first electronic die coupled to the first plurality of conductive pads and a second electronic die coupled to the second plurality of conductive pads.

In some aspects, the techniques described herein relate to an electronic-photonic package, wherein the electronic layer is disposed between the photonic layer and the first plurality of conductive pads, and the first plurality of conductive pads are coupled to the second plurality of TSVs.

In some aspects, the techniques described herein relate to an electronic-photonic package, wherein the photonic layer is disposed between the electronic layer and the first plurality of conductive pads, and the first plurality of conductive pads are coupled to the first plurality of TSVs.

In some aspects, the techniques described herein relate to an electronic-photonic package, wherein the photonic layer is patterned to include a 1-dimensional or a 2-dimensional array of photonic tiles that are optically coupled to one another and that are copies of a master photonic ile.

In some aspects, the techniques described herein relate to an electronic-photonic package, wherein the master photonic tile has an area that is between 4 cm2 and 10 cm2, and wherein the photonic layer has an area that is between 50 cm2 and 700 cm2.

In some aspects, the techniques described herein relate to an electronic-photonic package, wherein the controllable photonic devices include optical modulators and photodetectors, and wherein the electronic circuitry includes modulator drivers coupled to the optical modulators and transimpedance amplifiers coupled to the photodetectors.

In some aspects, the techniques described herein relate to a method for manufacturing an electronic-photonic package, including: fabricating a photonic integrated circuit (PIC) by: obtaining a photonic layer including a plurality of controllable photonic devices and a first plurality of through silicon vias (TSV); obtaining an electronic layer including a second plurality of TSVs and electronic circuitry; forming a substrate by hybrid-bonding the photonic layer to the electronic layer so that the first plurality of TSVs are coupled to the second plurality of TSVs and the electronic circuitry is configured to control the controllable photonic devices; and forming a plurality of conductive pads on a surface of the substrate.

In some aspects, the techniques described herein relate to a method, further including bonding an electronic die, including a plurality of serializer/deserializers (SerDes), to the surface of the substrate so that the plurality of SerDes are coupled to the plurality of conductive pads.

In some aspects, the techniques described herein relate to a method, wherein fabricating the PIC further includes, subsequent to hybrid-bonding the photonic layer to the electronic layer, singulating the PIC from the substrate.

In some aspects, the techniques described herein relate to a method, wherein the electronic layer further includes a plurality of front-end vias, and upon forming the plurality of conductive pads on the surface of the substrate, the plurality of front-end vias are coupled to the plurality of conductive pads.

### BRIEF DESCRIPTION OF THE DRAWINGS

Various aspects and embodiments of the application will be described with reference to the following figures. It should be appreciated that the figures are not necessarily drawn to scale. Items appearing in multiple figures are indicated by the same reference number in the figures in which they appear.

FIG. 1A illustrates an electronic-photonic package including a photonic integrated circuit (PIC) serving as a photonic interposer that supports optical-domain, inter-chip communication between electronic dies mounted on the PIC, in accordance with some embodiments.

FIG. 1B illustrates another electronic-photonic package including a PIC serving as a photonic interposer that supports optical-domain, inter-chip communication between electronic dies mounted on the PIC, in accordance with some embodiments.

FIG. 2A illustrates another electronic-photonic package including a PIC serving as a photonic interposer that supports optical-domain, inter-chip communication between electronic dies mounted on the PIC, in accordance with some embodiments.

FIG. 2B illustrates another electronic-photonic package including a PIC serving as a photonic interposer that supports optical-domain, inter-chip communication between electronic dies mounted on the PIC, in accordance with some embodiments.

FIG. 3A illustrates an example of a master photonic tile, in accordance with some embodiments.

FIG. 3B illustrates an example of a photonic layer fabricated using multiple instantiations of the master photonic tile of FIG. 3A, in accordance with some embodiments.

FIG. 4 illustrates an electronic-photonic package including a PIC serving as a photonic engine operating in conjunction with an electronic interposer to support inter-chip, hybrid electronic-photonic communication between electronic dies mounted on the electronic interposer, in accordance with some embodiments.

FIG. 5 illustrates the photonic layer and the electronic layer of FIG. 4 in additional detail, in accordance with some embodiments.

FIG. 6 illustrates a process for hybrid-bonding an electronic wafer to a photonic wafer, in accordance with some embodiments.

### DETAILED DESCRIPTION

Described herein are electronic-photonic packages including photonic integrated circuits (PIC) that are assembled using hybrid bonding techniques and that communicate with external electronic dies using through silicon vias (TSVs). PICs of the types described herein may be used to support optical-domain communication between electronic devices, whether in the form of inter-chip communication or intra-chip communication. Conventional PICs include photonic devices and electronic circuitry that are co-patterned on the same semiconductor substrate using photolithographic techniques. In co-patterned substrates, photonic elements (e.g., waveguides) and transistors are defined in the same semiconductor layers. Co-patterning photonic devices together with electronic circuitry on the same substrate is beneficial because this approach reduces manufacturing costs.

The inventors have recognized and appreciated, however, that co-patterning photonic devices together with electronic circuitry on the same substrate poses a major constraint. This approach is premised on the use of the same technology node to define both the photonic elements and the transistors. For example, both the photonic elements and the transistors may be fabricated using advanced nodes, such as a 7 nm-node, a 5 nm-node or a 3 nm-node. Alternatively, both the photonic elements and the transistors may be fabricated using legacy nodes, such as a 28 nm-node, a 40 nm-node, 65 nm-node or a 90 nm-node. Use of advanced nodes greatly benefits the performance of transistors, whether in terms of lower capacitance, improved parallelism, higher switching speed or reduced power consumption. However, the performance of photonic devices varies with the technology node to a much lesser extent. This is because the minimum feature size that can be patterned in photonic devices is primarily dictated by the wavelength of optical signals that the photonic devices are designed to support. For example, photonic devices designed to operate in the infrared spectrum present minimum features that are larger in size than in those designed to operate in the visible spectrum. Once the operational wavelength has been set, reducing the minimum feature size of a photonic device beyond a certain value is no longer beneficial.

Constraining the manufacturing process to use the same technology node for both types of circuits leads to significant trade-offs. On one hand, using larger technology nodes is suitable for photonic devices, but results in poor transistor performance. On the other hand, using smaller technology nodes is suitable for transistors, but results in substantially greater manufacturing costs without added benefits to the photonic devices.

Recognizing the limitations associated with conventional co-patterned approaches, the inventors have developed manufacturing techniques that permit fabrication of photonic devices and electronic circuitry using different technology nodes. For example, electronic circuitry can be patterned using an advanced node and photonic devices can be patterned using a legacy node. Once patterned, the substrate supporting the photonic devices is bonded to the substrate supporting the electronic circuitry.

The inventors have further recognized and appreciated that conventional techniques for bonding electronic substrates to photonic substrates have a few limitations. Some packaging techniques rely on die-die bonding, in which electronic dies are bonded to photonic dies on an individual basis. This approach is time-intensive because each die must be picked, aligned, and bonded individually. Additionally, this approach requires that each die be tested before bonding to avoid wasting a good die by pairing it with a defective one. This adds complexity and can result in lower yields. Further packaging techniques rely on solder reflow, a process used to form electrical and mechanical connections between substrates using solder. Solder provides both electrical interconnection and physical attachment between the substrates. For example, flip-chip technology often relies on solder bumps to connect a die to another die. During reflow, the solder bumps melt and form connections between the two surfaces. However, solder joints introduce resistive, capacitive, or inductive losses, ultimately leading to poor signal integrity, reducing speed and increasing power consumption.

To overcome these limitations, the inventors propose using wafer-wafer hybrid bonding. Hybrid bonding is a manufacturing technique used to join two semiconductor substrates that is based in part on chemical bonding and in part on mechanical interlocking at the molecular level. Prior to bonding, the surfaces of the substrates are polished to achieve extreme flatness, for example using chemical-mechanical polishing (CMP), to ensure intimate contact between the surfaces without gaps. The surfaces of the two substrates are subsequently brought into direct contact at the molecular level, eliminating the need for an intermediate adhesive or solder material. As such, conductive pads formed on the surface of one substrate come in direct electrical contact with conductive pads formed on the surface of the other substrate, without having to resort to solder bumps or other types of connections between the substrates.

Eliminating solder joints improves signal integrity because solder joints introduce resistive, capacitive, or inductive losses. Additionally, materials commonly used for direct bonding (e.g., copper) have better heat dissipation properties than solder alloys. This represents a significant improvement for PICs operating at high power or in compact designs where thermal management is critical. Lastly, soldering can create thermal stress during reflow due to the differences in thermal expansion coefficients (CTE) of materials. Eliminating solder mitigates these risks.

Hybrid bonding in accordance with some embodiments may be performed at wafer scale—an entire electronic wafer that has been pre-patterned with electronic circuitry is hybrid-bonded to an entire photonic wafer that has been pre-patterned with photonic devices. The wafers may be 6″, 9″, 12″, 15″ or 18″ in diameter, for example. Hybrid bonding in accordance with these embodiments is performed without having to first singulate individual dies. This approach is more desirable than die-die bonding in that it supports high-volume manufacturing, ensuring consistent performance and quality and reducing further handling and processing steps.

Additionally, wafer-wafer bonding techniques promote fabrication of TSVs on a large scale. TSVs are vertical electrical interconnections that pass through a silicon substrate, enabling communication between different layers in a 3D integrated circuit (IC) or system-on-chip (SoC). TSVs are fabricated during the back-end-of-line (BEOL) or packaging stage, as they connect dies post-front-end processing. TSVs differ from front-end vias in that front-end vias are fabricated during the front-end-of-line (FEOL) and are used to connect devices to higher levels of interconnects (local, intermediate, and global metal layers). Front-end vias are much smaller than TSVs, as they are designed to operate within the dimensions of the die's internal layers. For example, the side of a TSV may be a few micron while the size of a front-end via may be a few nanometers.

Leveraging the availability of TSVs using the manufacturing techniques described above, PICs in accordance with some embodiments communicate with electronic dies using TSVs. Additionally or alternatively, TSVs are used to support internal communication within a PIC, between the photonic layer and the electronic layer.

Electronic-photonic packages including PICs that are assembled using wafer-wafer hybrid bonding techniques and that are designed to communicate with external electronic dies using TSVs enable several system architectures. In one example, a system architecture involves a PIC serving as a photonic interposer that supports optical-domain, inter-chip communication between electronic dies mounted on the PIC or intra-chip, optical-domain communication between different sub-systems of an electronic die mounted on the PIC. In another example, a system architecture involves a PIC serving as a photonic engine operating in conjunction with an electronic interposer to support inter-chip, hybrid electronic-photonic communication between electronic dies mounted on the electronic interposer.

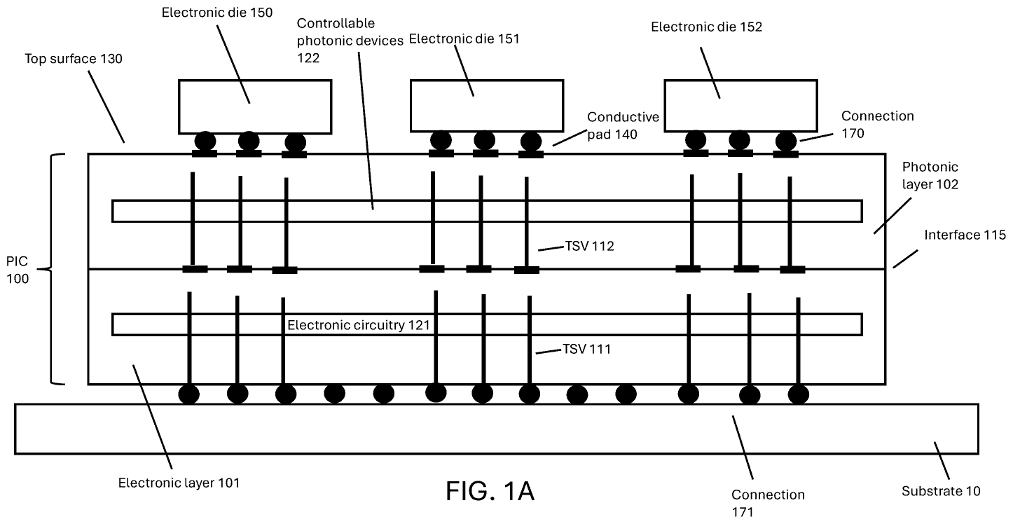

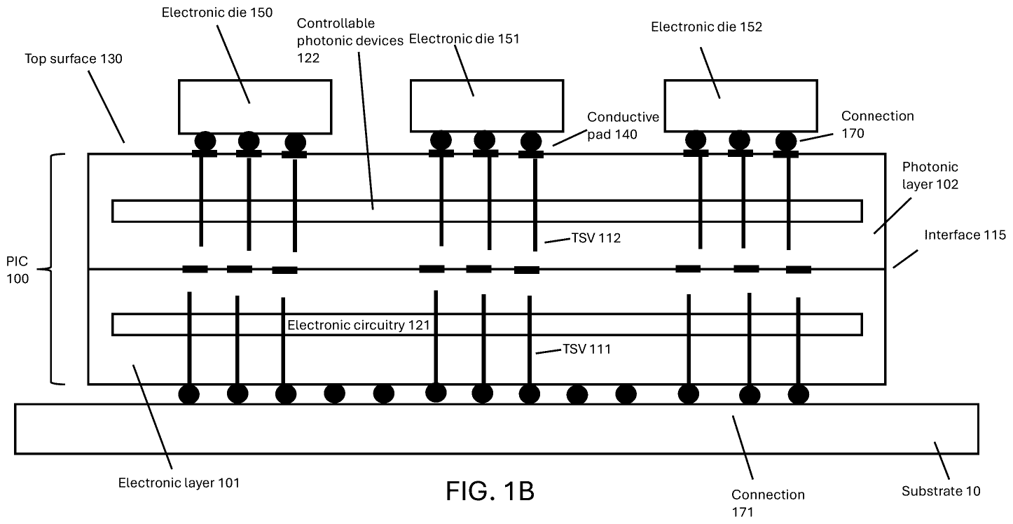

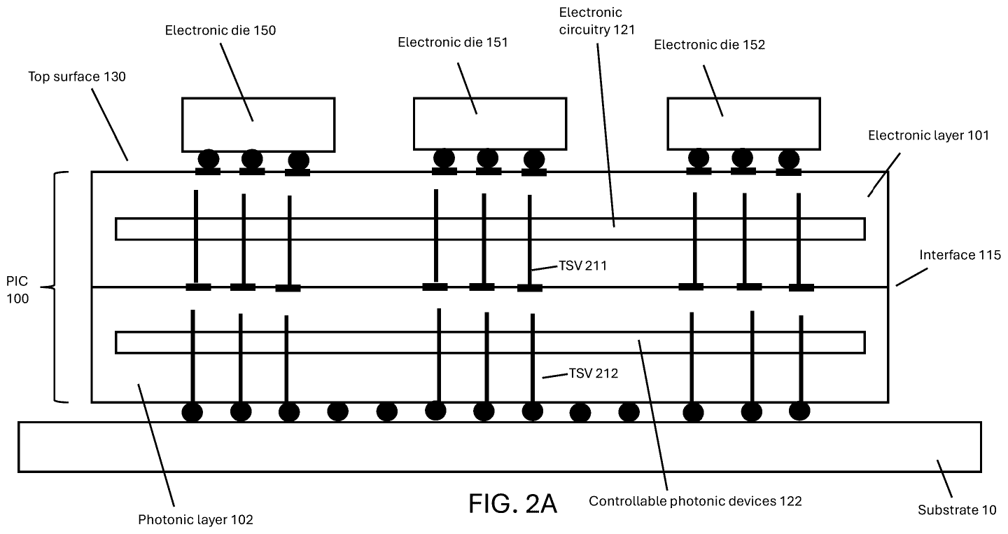

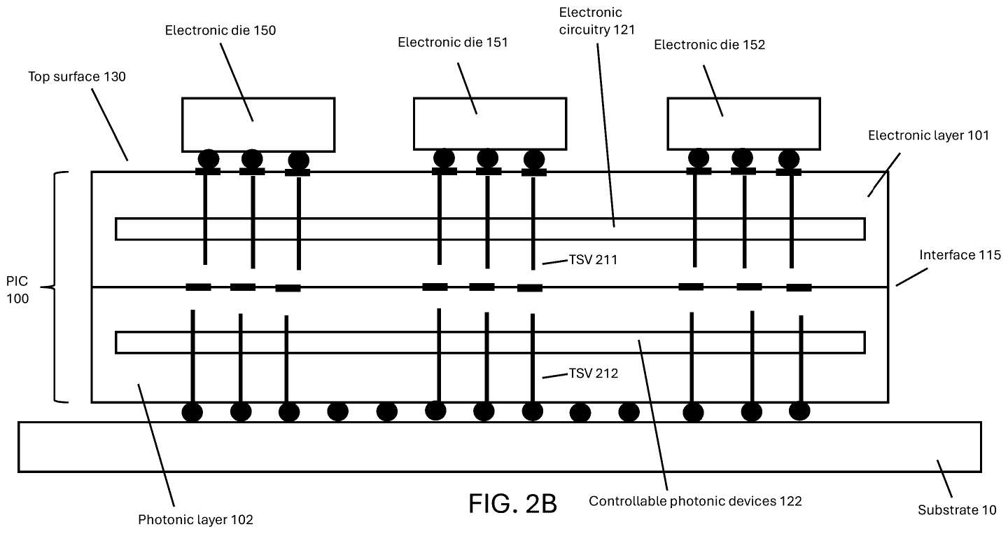

FIGS. 1A, 1B, 2A, 2B illustrate examples of electronic-photonic packages including a photonic integrated circuit (PIC) 100 serving as a photonic interposer that supports optical-domain, inter-chip communication between electronic dies mounted on the PIC. In these examples, the packages include three electronic dies 150, 151 and 152, although any other suitable number of dies is possible. The electronic dies may include processors, memory, graphic processing units, electronic switches, or any other types of electronic systems that would benefit from high-speed, low-power inter-chip communication.

PIC 100 is fabricated using hybrid bonding (e.g., wafer-wafer hybrid bonding). An electronic layer 101 is hybrid-bonded to a photonic layer 102. Interface 115 indicates the plane where the surfaces of electronic layer 101 and photonic layer 102 are joined. As discussed above, because the surfaces are connected via hybrid bonding, conductive pads formed on the surface of electronic layer 101 come in direct electrical contact with conductive pads formed on the surface of photonic layer 102 without having to resort to bumps or other types of external connections between the surfaces. This improves the integrity of the signals that travel from electronic layer 101 to photonic layer 102 and vice versa.

The PICS of FIGS. 1A-1B are similar to the PICS of FIGS. 2A-2B in that each PIC includes electronic circuitry 121 patterned in electronic layer 101 and controllable photonic devices 122 patterned in photonic layer 102. However, these packages differ in one respect. In FIGS. 1A-1B, photonic layer 102 is disposed between electronic layer 101 and electronic dies 150-152, while in FIGS. 2A-2B, it is electronic layer 101 that is disposed between photonic layer 102 and electronic dies 150-152. In each package, TSVs support communication between controllable photonic devices 122 and electronic circuitry 121. In FIG. 1A, the back side of photonic layer 102 is on the bottom and the top side of photonic layer 102 is on the top. Similarly, the back side of electronic layer 101 is on the bottom and the top side of electronic layer 101 is on the top. TSVs 111 are formed in electronic layer 101 and extend to the bottom side of electronic layer 102; TSVs 112 are formed in photonic layer 102 and extend to the bottom side of photonic layer 101. TSVs 112 are coupled to photonic devices 122, while TSVs 111 are coupled to electronic circuitry 121. TSVs 112 are indirectly coupled to TSVs 111 through front-end vias (not shown in FIG. 1A) formed in electronic layer 101. Further front-end vias (not shown in FIG. 1A) couple TSVs 112 to conductive pads 140.

The implementation of FIG. 1A is referred to as “face-to-back attach” in that the face of electronic layer 101 is attached to the back of photonic layer 102. By contrast, the implementation of FIG. 1B is referred to as “face-to-face attach” in that the face of electronic layer 101 is attached to the face of photonic layer 102. In this implementation, the back side of photonic layer 102 is on the top and the top side of photonic layer 102 is on the bottom. TSVs 112 are indirectly coupled to TSVs 111 through front-end vias formed in electronic layer 101 and front-end vias formed in photonic layer 102. Further implementations in which electronic layer 101 is flipped relative to what is shown in FIGS. 1A-1B—such that the back side of electronic layer 101 is on the top and the top side of electronic layer 101 is on the bottom—are also possible.

In FIG. 2A, TSVs 212 formed in photonic layer 102 are coupled to photonic devices 122, while TSVs 211 formed in electronic layer 101 are coupled to electronic circuitry 121. TSVs 212 are coupled to TSVs 211 indirectly though front-end vias (not shown in FIG. 2A) formed in photonic layer 102. Further front-end vias (not shown in FIG. 2A) couple TSVs 211 to conductive pads 140. In FIG. 2B, electronic layer 101 is flipped relative to what is shown in FIG. 2A. Additionally or alternatively, photonic layer 102 may flipped relative to what is shown in FIG. 2A.

In the packages of FIGS. 1A, 1B, 2A, 2B, PIC 100 connects to substrate 10 via connections 171 and to electronic dies 150-152 via connections 170. Connections 170 and 171 may be implemented using conductive bumps, balls, pillars, etc. Connections 171 allow substrate 10 to deliver power to PIC 100 and to exchange signals between substrate 10 and PIC 100. Similarly, connections 170 allow PIC 100 to deliver power to electronic dies 150-152 and to exchange signals between PIC 100 and electronic dies 150-152.

In the packages of FIGS. 1A, 1B, 2A, 2B, electronic circuitry 121 controls controllable photonic devices 122. Controllable photonic devices 122 may define a network of photonic switches configured to promote optical-domain communication among electronic dies 150-152 in a programmable fashion. Depending on the status of the photonic switches (set by electronic circuitry 121), any electronic die can transmit data to any other electronic die in the optical domain. As such, PIC 100 may be viewed as operating as a photonic interposer.

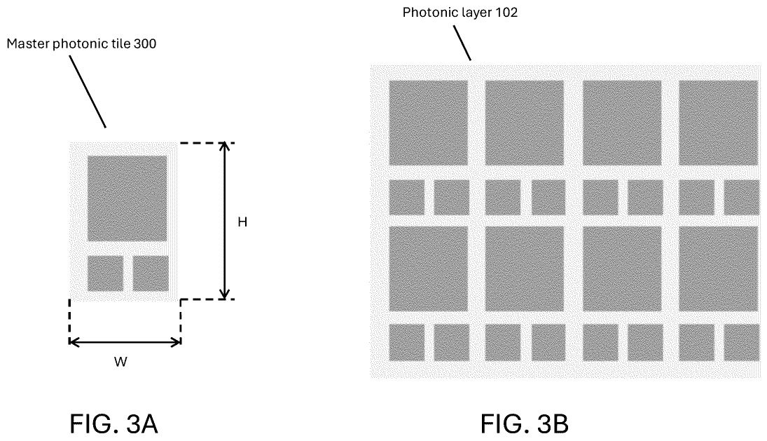

In some embodiments, photonic layer 102 may be fabricated in accordance with reticle stitching techniques. A step-and-repeat process produces multiple photonic tiles as instantiations (copies) of a master photonic tile. Therefore, the tiles share the same layout. The master tile may be designed to have waveguides that, once tiles are patterned adjacent to each other, optically couple to waveguides formed in the adjacent tile. FIG. 3A illustrates an example of a master photonic tile 300 in accordance with some embodiments. Master photonic tile 300 is patterned to include photonic devices, including waveguides, optical switches, modulators, photodetectors, multiplexers, demultiplexers, etc. Master photonic tile 300 represents a single reticle shot of a step-and-repeat process. As such, the dimension of master photonic tile 300 is dictated by the reticle size supported by the semiconductor foundry. For example, the width (W) of master photonic tile 300 may be between 10 mm and 30 mm, between 10 mm and 25 mm, between 10 mm and 20 mm, between 10 mm and 15 mm, between 15 mm and 30 mm, between 20 mm and 30 mm or between 25 mm and 30 mm. The height (H) of master photonic tile 300 may be between 20 mm and 40 mm, between 20 mm and 35 mm, between 20 mm and 30 mm, between 20 mm and 25 mm, between 25 mm and 40 mm, between 25 mm and 35 mm, between 25 mm and 30 mm or between 30 mm and 35 mm. In some embodiments, the area of master photonic tile 300 (W×H) may be between 4 cm² and 10 cm².

FIG. 3B illustrates an example of a photonic layer 102 fabricated using multiple instantiations of master photonic tile 300. In this arrangement, photonic layer 102 defines a 2-dimensional array including eight photonic tiles that are optically coupled to one another and that are copies of master photonic tile 300. Alternatively, 1-dimensional arrays of photonic tiles are also possible. Depending on the number of instantiations of master photonic tile 300 forming photonic layer 102, the area of photonic layer 102 may range from 50 cm² to 700 cm². In some embodiments, there may be as many instantiations of master photonic tile 300 as electronic dies mounted on PIC 100. For example, each photonic tile may support communication between a respective electronic die and the other photonic tiles of PIC 100.

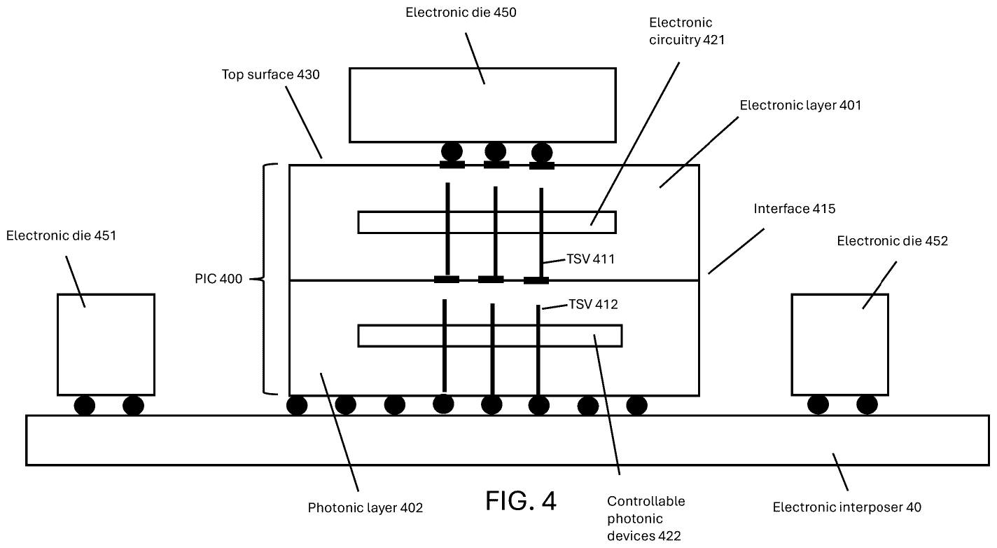

FIG. 4 illustrates an electronic-photonic package including a PIC 400 serving as a photonic engine operating in conjunction with an electronic interposer 40 to support inter-chip, hybrid electronic-photonic communication between electronic dies 451-452 mounted on the electronic interposer. PIC 400 may be viewed as serving as a photonic engine in that, although propagation of signals between the dies is performed in the electrical domain (within electronic interposer 40), switching is performed in the optical domain. In this example, the package includes two electronic dies 451-452, although any other suitable number of dies is possible. As in the packages of FIG. 1A, 1B, 2A, 2B, the electronic dies may include processors, memory, graphic processing units, electronic switches, or any other types of electronic systems that would benefit from high-speed, low-power inter-chip communication.

PIC 400 is fabricated using hybrid bonding (e.g., wafer-wafer hybrid bonding). As such, PIC 400 includes an electronic layer 401, a photonic layer 402 and an interface 415 that have the same characteristics as electronic layer 101, photonic layer 102 and interface 115, described above in connection with FIGS. 1A, 1B, 2A, 2B. TSVs 412, formed in photonic layer 402, are coupled to photonic devices 422, while TSVs 411, formed in electronic layer 401, are coupled to electronic circuitry 421. TSVs 412 are coupled to TSVs 411 indirectly as discussed above in connection with FIGS. 1A, 1B, 2A, 2B. Either photonic layer 402 or electronic layer 401 (or both) may be flipped relative to what is shown in FIG. 4.

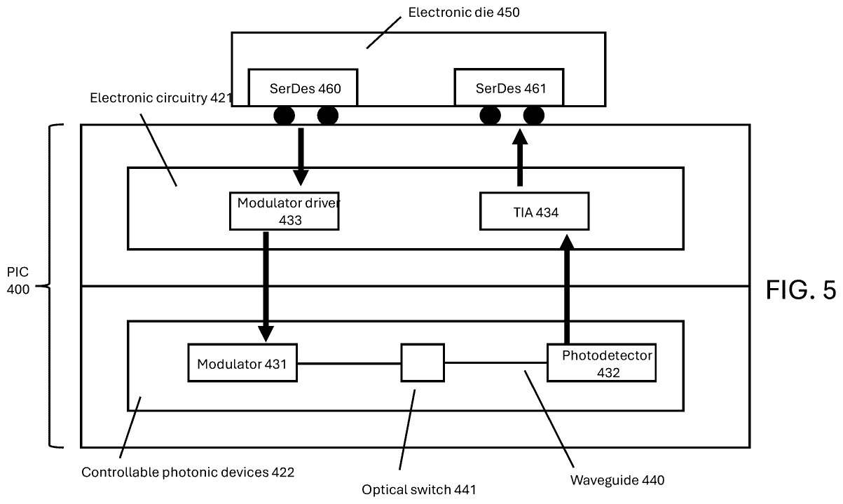

FIG. 5 illustrates the photonic layer and the electronic layer of FIG. 4 in additional detail. As shown, photonic devices 422 include modulators 431, optical switches 441, and photodetectors 432 (only one modulator, optical switch and photodetector are depicted for purposes of illustration). A waveguide 440 optical couples modulator 431 to photodetector 432 passing through optical switch 441. Optical switch 441 may be coupled to additional waveguides (not shown in FIG. 5) to permit selective communication between different dies mounted on electronic interposer 40.

Electronic circuitry 421 includes a modulator driver 433 for each modulator of photonic layer 402 and a transimpedance amplifier (TIA) 434 for each photodetector. In this example, electronic die 450 can include several serializer-deserializer (SerDes), although only two SerDes 460-461 are shown. The SerDes may be coupled to the modulator drivers and the TIAs, and may be used to convert parallel data into serial data (serialization) for transmission and convert the received serial data back into parallel data (deserialization). The SerDes enable high-speed data transmission by bridging the gap between the high-speed nature of photonic layer 402 and the slower nature of electronic interposer 40.

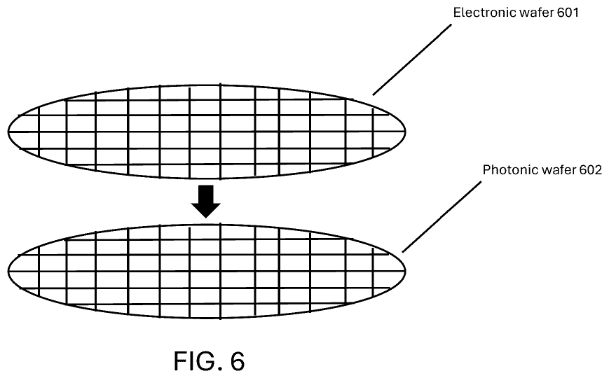

As described above, PICs of the types described herein may be fabricated using hybrid bonding. Accordingly, two semiconductor substrates are joined together based in part on chemical bonding and in part on mechanical interlocking at the molecular level. As further depicted in FIG. 6, hybrid bonding in accordance with some embodiments may be performed at wafer scale—an entire electronic wafer 601 that has been pre-patterned with electronic circuitry is hybrid bonded to an entire photonic wafer 602 that has been pre-patterned with photonic devices. The wafers may be 6″, 9″, 12″, 15″ or 18″ in diameter. Hybrid bonding in accordance with these embodiments is performed without having to first singulate individual dies. Instead, die singulation may be performed (e.g., using a die saw) subsequent to the bonding step.

Having thus described several aspects and embodiments of the technology of this application, it is to be appreciated that various alterations, modifications, and improvements will readily occur to those of ordinary skill in the art. Such alterations, modifications, and improvements are intended to be within the spirit and scope of the technology described in the application. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, and/or methods described herein, if such features, systems, articles, materials, and/or methods are not mutually inconsistent, is included within the scope of the present disclosure.

The definitions, as defined and used herein, should be understood to control over dictionary definitions, definitions in documents incorporated by reference and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some case and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The terms “approximately,” “substantially,” and “about” may be used to mean within ±20% of a target value in some embodiments. The terms “approximately,” “substantially,” and “about” may include the target value.

Use of ordinal terms such as “first,” “second,” “third,” etc., in the claims to modify a claim element does not by itself connotate any priority, precedence, or order of one claim element over another or the temporal order in which acts of a method are performed, but are used merely as labels to distinguish one claim element having a certain name from another claim element having a same name (but for use of the ordinal term) to distinguish the claim elements.

Also, the phraseology and terminology used herein is for the purpose of description and should not be regarded as limiting. The use of “including,” “comprising,” “having,” “containing,” “involving,” and variations thereof herein, is meant to encompass the items listed thereafter and equivalents thereof as well as additional items.

The terms “couple,” “coupled,” and “coupling,” when used in connection with optical components, are to be interpreted broadly to include both direct and indirect coupling. Two optical components are considered directly coupled if there are no intervening components between them. In contrast, two optical components are considered indirectly coupled if there is at least one intervening component between them, provided that the intervening component does not alter the general nature of the interaction between the optical components.

What is claimed is:

1. An electronic-photonic package, comprising:
a photonic integrated circuit (PIC) comprising:
a photonic layer comprising a plurality of controllable photonic devices and a first plurality of TSVs; and
an electronic layer hybrid-bonded to the photonic layer, the electronic layer comprising a second plurality of TSVs coupled to the first plurality of TSVs, and electronic circuitry configured to control the controllable photonic devices; and
a first electronic die mounted on the PIC and coupled to the first plurality of TSVs or the second plurality of TSVs.

2. The electronic-photonic package of claim 1, further comprising a second electronic die mounted on the PIC, wherein the controllable photonic devices permit optical communication between the first and second electronic dies.

3. The electronic-photonic package of claim 1, wherein the electronic layer is disposed between the photonic layer and the first electronic die, and the first electronic die is coupled to the second plurality of TSVs.

4. The electronic-photonic package of claim 1, wherein the photonic layer is disposed between the electronic layer and the first electronic die, and the first electronic die is coupled to the first plurality of TSVs.

5. The electronic-photonic package of claim 1, wherein the photonic layer is patterned to include a 1-dimensional or a 2-dimensional array of photonic tiles that are optically coupled to one another and that are copies of a master photonic tile.

6. The electronic-photonic package of claim 5, wherein the master photonic tile has an area that is between 4 cm² and 10 cm².

7. The electronic-photonic package of claim 6, wherein the photonic layer has an area that is between 50 cm² and 700 cm².

8. The electronic-photonic package of claim 1, wherein the controllable photonic devices comprise optical modulators and photodetectors, and wherein the electronic circuitry comprises modulator drivers coupled to the optical modulators and transimpedance amplifiers coupled to the photodetectors.

9. The electronic-photonic package of claim 8, wherein the electronic die comprises a first plurality of serializer-deserializers (SerDes) coupled to the modulator drivers and a second plurality of SerDes coupled to the transimpedance amplifiers.

10. An electronic-photonic package, comprising:
a photonic integrated circuit (PIC) comprising:
a photonic layer comprising a plurality of controllable photonic devices and a first plurality of TSVs; and
an electronic layer hybrid-bonded to the photonic layer, the electronic layer comprising a second plurality of TSVs coupled to the first plurality of TSVs, and electronic circuitry configured to control the controllable photonic devices; and
a first plurality of conductive pads formed on a surface of the PIC and coupled to the first plurality of TSVs or the second plurality of TSVs.

11. The electronic-photonic package of claim 10, further comprising a second plurality of conductive pads formed on the surface of the PIC, wherein the controllable photonic devices permit optical communication between a first electronic die coupled to the first plurality of conductive pads and a second electronic die coupled to the second plurality of conductive pads.

12. The electronic-photonic package of claim 10, wherein the electronic layer is disposed between the photonic layer and the first plurality of conductive pads, and the first plurality of conductive pads are coupled to the second plurality of TSVs.

13. The electronic-photonic package of claim 10, wherein the photonic layer is disposed between the electronic layer and the first plurality of conductive pads, and the first plurality of conductive pads are coupled to the first plurality of TSVs.

14. The electronic-photonic package of claim 10, wherein the photonic layer is patterned to include a 1-dimensional or a 2-dimensional array of photonic tiles that are optically coupled to one another and that are copies of a master photonic tile.

15. The electronic-photonic package of claim 14, wherein the master photonic tile has an area that is between 4 cm² and 10 cm², and wherein the photonic layer has an area that is between 50 cm² and 700 cm².

16. The electronic-photonic package of claim 10, wherein the controllable photonic devices comprise optical modulators and photodetectors, and wherein the electronic circuitry comprises modulator drivers coupled to the optical modulators and transimpedance amplifiers coupled to the photodetectors.

17. A method for manufacturing an electronic-photonic package, comprising:
fabricating a photonic integrated circuit (PIC) by:
obtaining a photonic layer comprising a plurality of controllable photonic devices and a first plurality of through silicon vias (TSV);
obtaining an electronic layer comprising a second plurality of TSVs and electronic circuitry;
forming a substrate by hybrid-bonding the photonic layer to the electronic layer so that the first plurality of TSVs are coupled to the second plurality of TSVs and the electronic circuitry is configured to control the controllable photonic devices; and
forming a plurality of conductive pads on a surface of the substrate.

18. The method of claim 17, further comprising bonding an electronic die, comprising a plurality of serializer/deserializers (SerDes), to the surface of the substrate so that the plurality of SerDes are coupled to the plurality of conductive pads.

19. The method of claim 17, wherein fabricating the PIC further comprises, subsequent to hybrid-bonding the photonic layer to the electronic layer, singulating the PIC from the substrate.

20. The method of claim 17, wherein the electronic layer further comprises a plurality of front-end vias, and upon forming the plurality of conductive pads on the surface of the substrate, the plurality of front-end vias are coupled to the plurality of conductive pads.
